(19) United States
(12) Patent Application Publication
(10) Pub. No.: US 2025/0294948 A1
(43) Pub. Date: Sep. 18, 2025

(54) DISPLAY DEVICE AND METHOD OF MANUFACTURING THE SAME

(71) Applicant: Japan Display Inc., Tokyo (JP)

(72) Inventor: Keisuke ASADA, Tokyo (JP)

(73) Assignee: Japan Display Inc., Tokyo (JP)

(21) Appl. No.: 19/077,099

(22) Filed: Mar. 12, 2025

(30) Foreign Application Priority Data
Mar. 15, 2024 (JP) 2024-040694

(51) Int. Cl. H10H 29/80; H10H 29/01; H10H 29/49

(52) U.S. Cl. CPC H10H 29/8321; H10H 29/012; H10H 29/49

(57) ABSTRACT

A method of manufacturing a display device includes a step of attaching a plurality of LED elements to an adhesive resin layer of a transfer substrate and a step of applying a thermal treatment to a plurality of bump electrodes, whereby electrodes of the plurality of LED elements are bonded to the plurality of bump electrodes of an array substrate. The array substrate has a mounting region to which the plurality of LED elements are mounted from the transfer substrate. Planar areas of the bump electrodes provided in a peripheral edge portion of the mounting region are larger than a planar area of the bump electrode provided in a central portion of the mounting region.

### CROSS-REFERENCE TO RELATED APPLICATION

The present application claims priority to Japanese Patent Application No. 2024-040694 filed on Mar. 15, 2024, the disclosure of which is incorporated herein by reference.

### TECHNICAL FIELD

This disclosure relates to a display device and a method of manufacturing the same.

### BACKGROUND

As a display device, there is an LED (Light Emitting Diode) display device in which a plurality of light emitting diode elements that are self-luminous elements are arranged in a matrix on a substrate. For example, Patent Document 1 (US Patent Application Publication No. 2019/0096774) discloses a technique of transferring a plurality of microdevices (LEDS) from a template to a receiver substrate. Also, Patent Document 2 (Japanese Unexamined Patent Application Publication No. 2019-511838) discloses a technique of transferring three types of LED elements from a growth substrate to a target substrate.

### SUMMARY

When transferring a plurality of LED elements to a transfer substrate, the plurality of LED elements are attached to an adhesive resin layer of the transfer substrate. If a thermal treatment is applied when transferring the plurality of LED elements from the transfer substrate to an array substrate (backplane), thermal expansion may occur in the adhesive resin layer due to the influence of the thermal treatment. As a result, there is a fear that the pitches of the plurality of LED elements attached to the adhesive resin layer change, and some LED elements cannot be mounted at correct positions on the array substrate. In other words, the connection failure of LED elements occur and the reliability of the display device is lowered.

A main object of this application is to improve the reliability of the display device by suppressing the connection failure of the LED elements. Other objects and novel features will be apparent from the description of this specification and the accompanying drawings.

A method of manufacturing a display device according to one embodiment includes: (a) a step of preparing a light emitting element holding substrate on which a plurality of inorganic light emitting elements are formed, a second substrate having a second adhesive resin layer, and an array substrate having a plurality of terminals and a plurality of bump electrodes formed on the plurality of terminals; (b) after the step (a), a step of attaching the plurality of inorganic light emitting elements on the light emitting element holding substrate to the second adhesive resin layer; (c) after the step (b), a step of applying a thermal treatment to the plurality of bump electrodes in a state where the plurality of inorganic light emitting elements are attached to the second adhesive resin layer, whereby first electrodes of the plurality of inorganic light emitting elements are bonded to the plurality of bump electrodes; and (d) after the step (c), detaching the plurality of inorganic light emitting elements from the second substrate. The array substrate has a mounting region to which the plurality of inorganic light emitting elements are mounted from the second substrate, and planar areas of the bump electrodes provided in a peripheral edge portion of the mounting region are larger than a planar area of the bump electrode provided in a central portion of the mounting region.

A display device according to one embodiment includes: a plurality of inorganic light emitting elements each having a first electrode; and an array substrate having a plurality of terminals and a plurality of bump electrodes formed on the plurality of terminals. The first electrodes of the plurality of inorganic light emitting elements are bonded to the plurality of bump electrodes, the array substrate has a mounting region to which the plurality of inorganic light emitting elements are mounted from one transfer substrate, and planar areas of the bump electrodes provided in a peripheral edge portion of the mounting region are larger than a planar area of the bump electrode provided in a central portion of the mounting region.

### BRIEF DESCRIPTION OF DRAWINGS

FIG. 1 is a plan view illustrating a display device in a first embodiment.

FIG. 2 is a circuit diagram illustrating a periphery of a pixel in the first embodiment.

FIG. 3 is a cross-sectional view illustrating a connection between an array substrate and an LED element in the first embodiment.

FIG. 4 is an enlarged cross-sectional view illustrating a modification of the LED element.

FIG. 5 is a plan view illustrating an LED holding substrate in the first embodiment.

FIG. 6 is an enlarged cross-sectional view illustrating a part of the LED holding substrate in the first embodiment.

FIG. 7 is a cross-sectional view illustrating a transfer substrate in the first embodiment.

FIG. 8 is an enlarged cross-sectional view illustrating a part of the array substrate in the first embodiment.

FIG. 9 is a plan view schematically illustrating the array substrate in the first embodiment.

FIG. 10 is a plan view schematically illustrating a layout of LED elements attached to the transfer substrate in the first embodiment.

FIG. 11 is a cross-sectional view illustrating a state of mounting the LED elements on the array substrate in the first embodiment.

FIG. 12 is a plan view schematically illustrating a mounting region of an array substrate in a studied example.

FIG. 13 is a cross-sectional view illustrating a state of mounting LED elements on the array substrate in the studied example.

FIG. 14 is a flowchart illustrating a manufacturing process of the display device in the first embodiment.

FIG. 15 is a cross-sectional view illustrating a manufacturing step of the display device in the first embodiment.

FIG. 16 is a cross-sectional view illustrating a manufacturing step of the display device subsequent to FIG. 15.

FIG. 17 is a cross-sectional view illustrating a manufacturing step of the display device subsequent to FIG. 16.

FIG. 18 is a cross-sectional view illustrating a manufacturing step of the display device subsequent to FIG. 17.

FIG. 19 is a cross-sectional view illustrating a manufacturing step of the display device subsequent to FIG. 18.

FIG. 20 is cross-sectional FIG. 20 a view illustrating a manufacturing step of the display device subsequent to FIG. 19.

FIG. 21 is a cross-sectional view illustrating a manufacturing step of the display device subsequent to FIG. 20.

### DETAILED DESCRIPTION OF THE INVENTION

Hereinafter, each embodiment of the present invention will be described with reference to drawings. Note that the disclosure is merely an example, and it is a matter of course that any alteration that is easily made by a person skilled in the art while keeping a gist of the present invention is included in the range of the present invention. In addition, the drawings schematically illustrate a width, a thickness, a shape, and the like of each portion as compared with actual aspects in order to make the description clearer, but the drawings are merely examples and do not limit the interpretation of the present invention. Further, the same elements as those described in relation to the foregoing drawings are denoted by the same or related reference characters in this specification and the respective drawings, and detailed descriptions thereof will be omitted as appropriate.

### First Embodiment

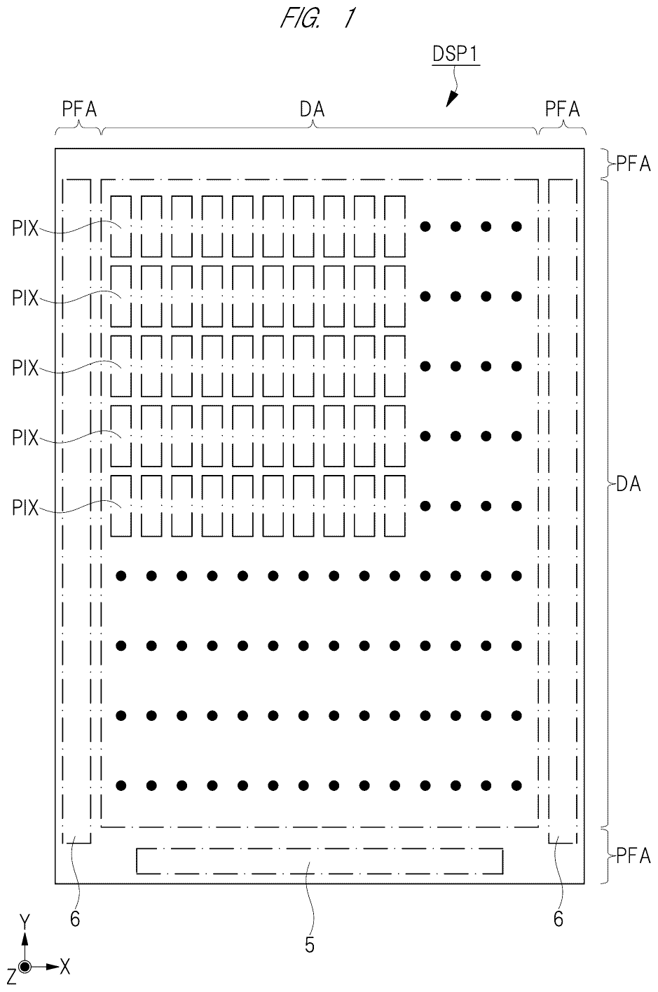

A display device DSP1 in a first embodiment will be described below with reference to FIG. 1 to FIG. 11.

The display device DSP1 is, for example, a micro LED display device including a plurality of LED elements (inorganic light emitting elements) 20 as a plurality of micro LED elements. Micro LED elements have a smaller element size (outer diameter dimension) than general LED elements, and thus have the advantage of being able to display high-definition images.

Note that organic light emitting diode (OLED) elements are known as light emitting diode elements that are self-luminous elements, but the LED element 20 described in the first embodiment is distinguished from the organic light emitting diode element.

### <Display Device>

FIG. 1 is a plan view illustrating a configuration example of the display device DSP1. In FIG. 1, each of a boundary between a display region DA and a peripheral region PFA, a control circuit 5, a drive circuit 6, and a plurality of pixels PIX is indicated by a one-dot dashed line.

As illustrated in FIG. 1, the display device DSP1 includes the display region DA, the peripheral region PFA surrounding the display region DA in a frame shape, the plurality of pixels PIX arranged in a matrix in the display region DA, the control circuit 5, and the drive circuit 6. Note that the control circuit 5 and the drive circuit 6 are formed on a substrate 10 of an array substrate SUB described later.

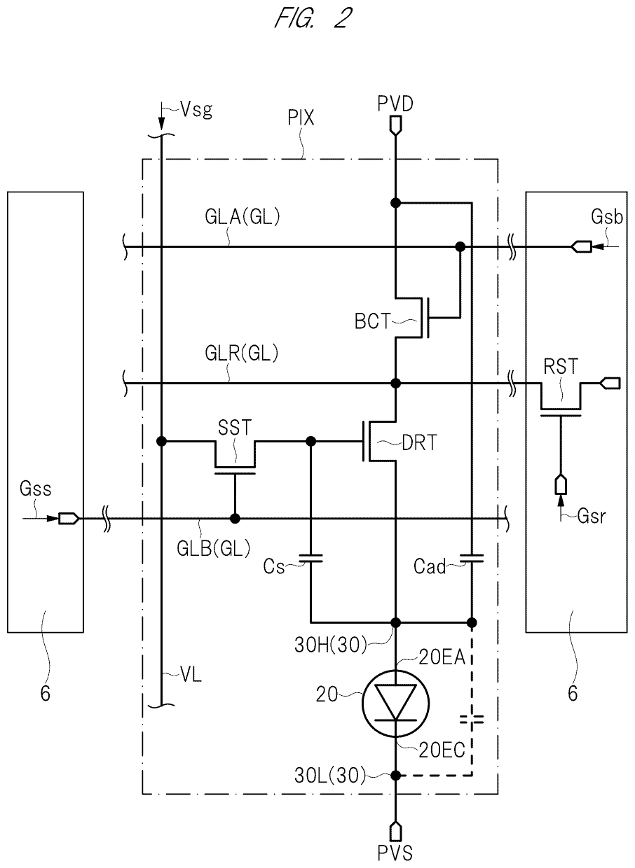

The control circuit 5 is a control circuit configured to control the driving of a display function of the display device DSP1. For example, the control circuit 5 is a driver IC (Integrated Circuit) mounted on the substrate 10. In FIG. 1, the control circuit 5 is arranged along one short side of the four sides of the substrate 10. Furthermore, in the first embodiment, the control circuit 5 includes a signal line drive circuit configured to drive video signal lines VL (see FIG. 2) connected to the plurality of pixels PIX.

However, the position and configuration example of the control circuit 5 are not limited to those in the example illustrated in FIG. 1, and there are various modifications. For example, in FIG. 1, a circuit board such as a flexible board may be connected to the position illustrated as the control circuit 5, and the above-described driver IC may be mounted on the circuit board. Further, for example, the signal line drive circuit configured to drive the video signal lines VL may be formed separately from the control circuit 5.

The drive circuit 6 is a circuit configured to drive scan signal lines GL in the plurality of pixels PIX. The drive circuit 6 drives the plurality of scan signal lines GL based on control signals from the control circuit 5. In FIG. 1, the drive circuit 6 is arranged along each of two long sides of the four sides of the substrate 10.

However, the position and configuration example of the drive circuit 6 are not limited to those in the example illustrated in FIG. 1, and there are various modifications. For example, in FIG. 1, a circuit board such as a flexible board may be connected to the position illustrated as the control circuit 5, and the above-described drive circuit 6 may be mounted on the circuit board.

Next, a circuit configuration example of the pixel PIX will be described with reference to FIG. 2. Note that FIG. 2 illustrates one pixel PIX representatively, but each of the plurality of pixels PIX illustrated in FIG. 1 includes the circuit similar to the pixel PIX illustrated in FIG. 2. In the following description, the circuit including a switch, a capacitor, and the LED element 20 in the pixel PIX may be referred to as a pixel circuit. The pixel circuit is a voltage signal circuit configured to control the light emission state of the LED element 20 in response to a video signal Vsg supplied from the control circuit 5 (see FIG. 1).

As illustrated in FIG. 2, the pixel PIX includes the LED element 20. The LED element 20 has an anode electrode 20EA and a cathode electrode 20EC. Each of the anode electrode 20EA and the cathode electrode 20EC of the LED element 20 is electrically connected to a terminal 30 of the pixel PIX. In FIG. 2, the cathode electrode 20EC of the LED element 20 is connected to a terminal 30L and the anode electrode 20EA of the LED element 20 is connected to a terminal 30H. A potential PVS which is a relatively low fixed potential (low potential) is supplied to the terminal 30L, and a potential PVD which is a higher fixed potential (high potential) than the potential supplied to the terminal 30L is supplied to the terminal 30H.

The pixel PIX includes an output switch BCT, a drive transistor DRT, and a pixel switch SST. The output switch BCT is a transistor configured to control a light emission time of the LED element 20 in response to a control signal Gsb supplied from the drive circuit 6. The drive transistor DRT is a transistor configured to control the amount of drive current supplied to the anode electrode 20EA of the LED element 20 in response to the video signal Vsg. The pixel switch SST is a transistor configured to control the connection state (on or off state) between the pixel circuit and the video signal line VL in response to a control signal Gss.

Also, the drive circuit 6 includes a reset switch RST configured to control the input of a reset potential. Each of the output switch BCT, the drive transistor DRT, the pixel switch SST, and the reset switch RST is, for example, a thin film transistor. When the pixel switch SST is in an on state, the video signal Vsg is input to the pixel circuit from the video signal line VL.

The drive circuit 6 includes a shift register circuit, an output buffer circuit, and the like (not illustrate). The drive circuit 6 outputs pulses based on a horizontal scanning start pulse transmitted from the control circuit 5 (see FIG. 1), and outputs the control signal Gss, the control signal Gsb, and a control signal Gsr.

The plurality of scan signal lines GL include a scan signal line GLA, a scan signal line GLB, and a reset wiring GLR. Each of the plurality of scan signal lines GL extends in the X direction. The scan signal line GLA is connected to a gate electrode of the output switch BCT. When the control signal Gsb is supplied to the scan signal line GLA, the output switch BCT is turned on. The scan signal line GLB is connected to a gate electrode of the pixel switch SST. When the control signal Gss is supplied to the scan signal line GLB, the pixel switch SST is turned on. The reset wiring GLR is connected between the output switch BCT and the drive transistor DRT and to a drain electrode of the reset switch RST. When the control signal Gsr which is a reset signal is supplied to a gate electrode of the reset switch RST, a reset potential is supplied to the reset wiring GLR.

The pixel PIX has a storage capacitance Cs and an auxiliary capacitance Cad. The storage capacitance Cs is connected between a gate electrode of the drive transistor DRT and the terminal 30H. The auxiliary capacitance Cad is connected between a source electrode of the output switch BCT and the terminal 30H. The auxiliary capacitance Cad is a capacitive element for adjusting the amount of light emission current, and the auxiliary capacitance Cad may not be provided as a modification.

### <Connection Between Array Substrate and LED Element>

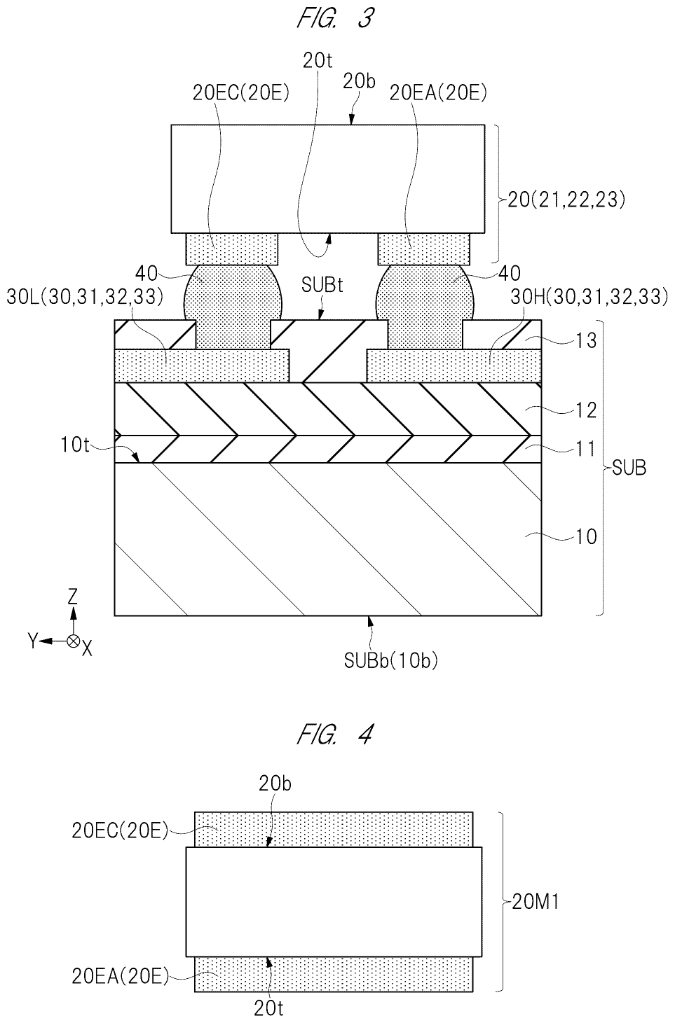

As illustrated in FIG. 3, the display device DSP1 includes the array substrate (backplane) SUB. The array substrate SUB is made up of the substrate 10, an inorganic insulating layer 11, an organic insulating layer 12, and an organic insulating layer 13. The substrate 10 has a surface 10t and a surface 10b on an opposite side of the surface 10t. The inorganic insulating layer 11 is formed on the surface 10t, the organic insulating layer 12 is formed on the inorganic insulating layer 11, and the organic insulating layer 13 is formed on the organic insulating layer 12. The array substrate SUB has a surface SUBt and a surface SUBb on an opposite side of the surface SUBt. In the first embodiment, the surface SUBb conforms to the surface 10b and the surface SUBt conforms to an upper surface of the organic insulating layer 13.

Also, the array substrate SUB includes various circuits provided in the pixel PIX described with reference to FIG. 2. For example, the semiconductor layers of the thin film transistors constituting the output switch BCT, the drive transistor DRT, and the pixel switch SST illustrated in FIG. 2 are formed in a circuit layer in the inorganic insulating layer 11. Some of a plurality of inorganic insulating films constituting the inorganic insulating layer 11 are used as base layers for forming the thin film transistors, and others thereof are used as gate insulating films of the thin film transistors.

Further, the array substrate SUB includes the plurality of terminals 30 and a plurality of bump electrodes (conductive bonding materials) 40 formed on the plurality of terminals 30. The plurality of terminals 30 are formed on the organic insulating layer 12. The organic insulating layer 13 has an opening through which a part of the terminal 30 is exposed. The bump electrode 40 is electrically connected to the terminal 30 in the opening. The terminal 30 is made of, for example, a metal material such as aluminum, copper, or titanium or an alloy material mainly containing the metal material mentioned above. The bump electrode 40 is made of, for example, a conductive material such as solder.

The LED element 20 is mounted on the array substrate SUB. The LED element 20 has a surface 20t and a surface 20b on an opposite side of the surface 20t. The LED element 20 includes a plurality of electrodes 20E arranged on the surface 20t. The plurality of electrodes 20E include the anode electrode 20EA and the cathode electrode 20EC.

The anode electrode 20EA is electrically connected to the terminal through the bump electrode 40. The cathode electrode 20EC is electrically connected to the terminal 30L through the bump electrode 40. In FIG. 3, one LED element 20 is illustrated, but the plurality of LED elements 20 are mounted in a matrix on the array substrate SUB. The display device DSP1 displays an image by driving the plurality of LED elements 20 mounted on the array substrate SUB. The light from the LED element 20 is emitted from, for example, the side of the surface 20b.

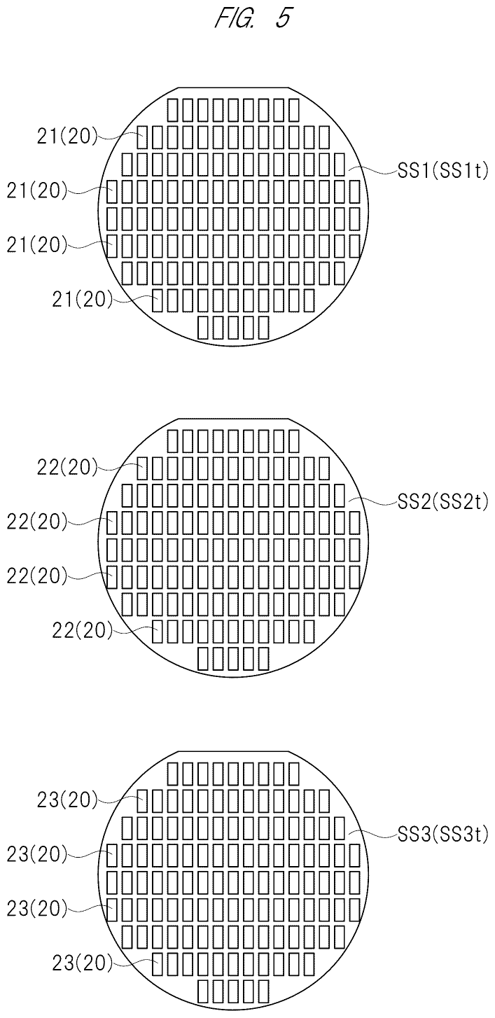

Note that the example in which both the anode electrode 20EA and the cathode electrode EC are arranged on the surface 20t is illustrated in FIG. 3. However, there are various modifications for the structure of the LED element 20. For example, as illustrated in FIG. 4, in a case of an LED element 20M1, the cathode electrode 20EC is provided on the surface 20b and the anode electrode 20EA is provided on the surface 20t. When replacing the LED element 20 in FIG. 3 with the LED element 20M1 in FIG. 4, the terminal 30L connected to the cathode electrode 20EC is provided on the surface 20b of the LED element 20M1.

### <Details of LED Holding Substrate and LED Element>

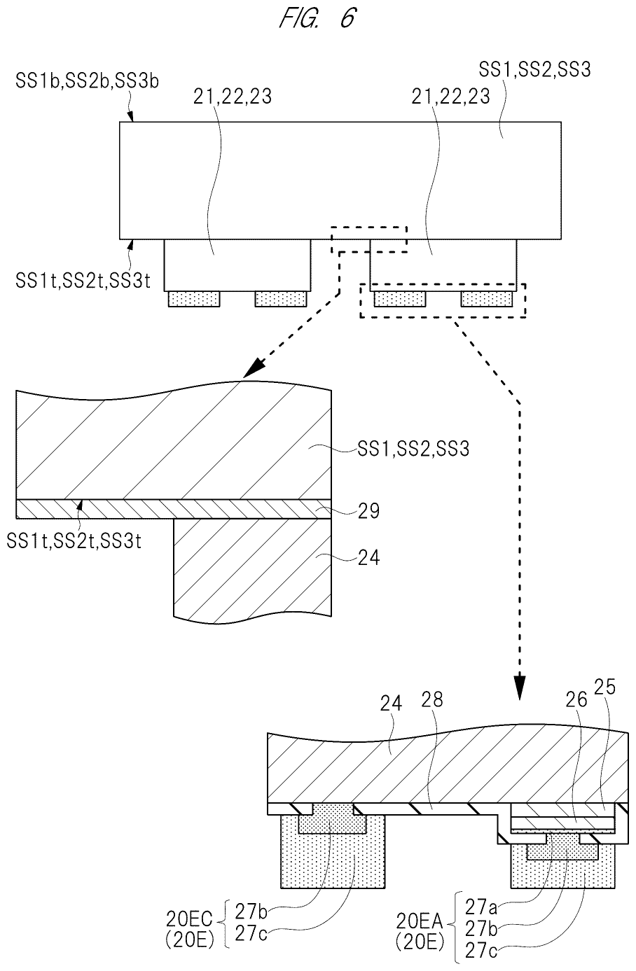

LED holding substrates (light emitting element holding substrates) SS1, SS2, and SS3 and a detailed structure of the LED element 20 will be described below with reference to FIG. 5 and FIG. 6.

As illustrated in FIG. 5, the LED holding substrates SS1, SS2, and SS3 (hereinafter, simply referred to as substrates SS1, SS2 and SS3) have surfaces SS1t, SS2t, and SSt3 and surfaces SS1b, SS2b, and SSb3 on an opposite side of the surfaces SS1t, SS2t, and SSt3. The LED elements 20 configured to emit the light of different colors are formed in a matrix on each of the surfaces SS1t, SS2t, and SSt3.

For example, a plurality of LED elements 21 for emitting red light are arranged in a matrix on the substrate SS1. A plurality of LED elements 22 for emitting green light are arranged in a matrix on the substrate SS2. A plurality of LED elements 23 for emitting blue light are arranged in a matrix on the substrate SS3.

Each of the substrates SS1, SS2, and SS3 is a sapphire substrate. The LED elements 21, 22, and 23 are formed by, for example, stacking metal films, insulating films, semiconductor films, and others on the sapphire substrates. In other words, the substrates SS1, SS2, and SS3 are substrates for manufacturing LEDS (LED wafers).

The detailed structure of the LED element 20 will be described below with reference to FIG. 6, but the substrates SS1, SS2, and SS3 have the same cross-sectional structures, and the LED elements 21, 22, and 23 have the same cross-sectional structures. Therefore, the substrate SS1 provided with the plurality of LED elements 21 will be described below as a representative example.

As illustrated in FIG. 6, the LED element 21 includes an N type semiconductor layer 24 formed on the substrate SS1, an active layer 25 formed on the N type semiconductor layer 24, and a P type semiconductor layer 26 formed on the active layer 25. The N type semiconductor layer 24 is formed as a base layer common to the anode electrode 20EA and the cathode electrode 20EC, and the active layer 25 and the P type semiconductor layer 26 are stacked on the side of the anode electrode 20EA.

On the side of the anode electrode 20EA, a transparent electrode layer 27a is formed on the P type semiconductor layer 26. The transparent electrode layer 27a on the side of the anode electrode 20EA and the N type semiconductor layer 24 on the side of the cathode electrode 20EC are covered with a passivation film 28 which is an inorganic insulating film. The passivation film 28 has openings at the positions where the anode electrode 20EA and the cathode electrode 20EC are formed. A metal electrode layer 27c is stacked on each of the openings via a seed layer 27b.

The anode electrode 20EA is a stacked body including the transparent electrode layer 27a, the seed layer 27b, and the metal electrode layer 27c. The cathode electrode 20EC is a stacked body including the seed layer 27b and the metal electrode layer 27c. Further, a buffer layer 29 made of gallium nitride is formed between the N type semiconductor layer 24 and the substrate SS1.

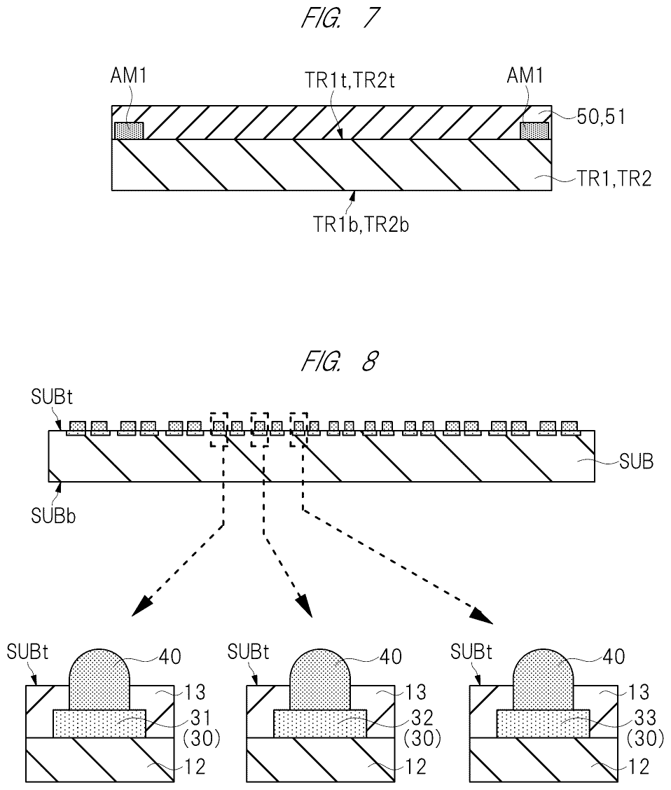

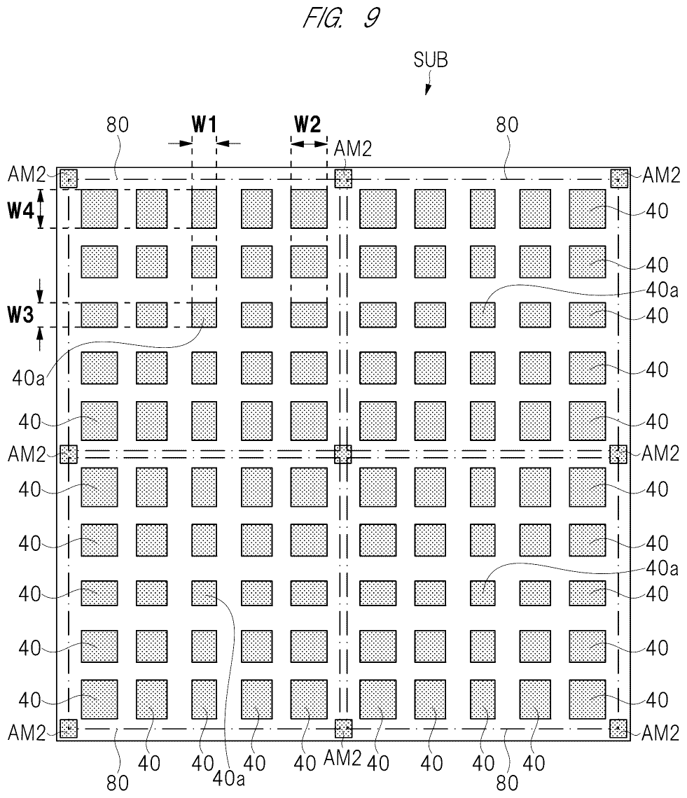

The LED elements 20 (LED elements 21, 22, and 23) are transferred from the substrates SS1, SS2, and SS3 to transfer substrates TR1 and TR2 in FIG. 7 described later, and then mounted on the array substrate SUB in FIG. 8 and FIG. 9 described later from the transfer substrates TR1 and TR2. <Configuration of Transfer Substrate>

As illustrated in FIG. 7, the transfer substrate TR1 has a surface TR1t, a surface TR1b on an opposite side of the surface TR1t, and an adhesive resin layer 50 formed on the surface TR1t. The transfer substrate TR2 has a surface TR2t, a surface TR2b on an opposite side of the surface TR2t, and an adhesive resin layer 51 formed on the surface TR2t. Though not illustrated, a planar shape of the transfer substrates TR1 and TR2 is quadrangular.

The transfer substrates TR1 and TR2 are made of, for example, a glass substrate. The adhesive resin layers 50 and 51 are transparent (transmissive to visible light) and are made of, for example, a silicone-based, polyimide-base, acrylic-based, or epoxy-based resin material. Further, the adhesive resin layers 50 and 51 have adhesiveness capable of holding the LED element 20. Note that the adhesive strength of the adhesive resin layer 51 to the LED element 20 is greater than the adhesive strength of the adhesive resin layer 50 to the LED element 20. The adhesive resin layer 50 is formed in a region corresponding to a mounting region of the array substrate described later.

Also, alignment marks AM1 are provided in some cases on the surfaces TR1t and TR2t so as to be covered with the adhesive resin layers 50 and 51, respectively. In this case, the alignment mark AM1 is made of a metal material such as aluminum, copper, or titanium or an alloy material mainly containing the metal material mentioned above.

### <Configuration of Array Substrate>

The array substrate SUB will be described below with reference to FIG. 8 and FIG. 9. Note that the array substrate SUB illustrated in FIG. 8 is a part of the array substrate SUB illustrated in FIG. 9, and corresponds to one mounting region 80. Also, in FIG. 9, the number, size, and others of the bump electrodes 40 are simplified as compared with the illustration in FIG. 8 and others in order to make the description easily understood.

As illustrated in FIG. 8, the array substrate SUB has the plurality of terminals 30. The plurality of terminals 30 include terminals 31 to be electrically connected to the LED elements 21, terminals 32 to be electrically connected to the LED elements 22, and terminals 33 to be electrically connected to the LED elements 23. The terminals 31, 32, and 33 are each arranged in a matrix so as to correspond to the positions of the pixels PIX illustrated in FIG. 1. The plurality of bump electrodes 40 are formed on the plurality of terminals 30.

As illustrated in FIG. 9, the array substrate SUB has the mounting region 80 to which the plurality of LED elements 20 are mounted from one transfer substrate TR2. The array substrate SUB has the plurality of mounting regions 80, and an example in which the array substrate SUB has four mounting regions 80 is illustrated here. Also, an alignment mark AM2 is provided at each of four corners of each mounting region 80. The alignment mark AM2 is made of, for example, the same metal material as that of the terminal 30, and is used when aligning the transfer substrate TR2 and the array substrate SUB.

The plurality of bump electrodes 40 are arranged in a matrix in the plurality of mounding regions 80. Here, planar areas of the bump electrodes 40 provided in a peripheral edge portion of the mounting region 80 are larger than a planar area of a bump electrode 40a provided in a central portion of the mounting region 80. More specifically, the planar areas of the plurality of bump electrodes 40 gradually increase as approaching the peripheral edge portion from the central portion mentioned above.

In other words, widths of the plurality of bump electrodes 40 increase in the row direction as the distance in the row direction from the bump electrode 40a provided in the central portion increases, and increase in the column direction as the distance in the column direction from the bump electrode 40a increases. Namely, in the row direction, a width W2 of the bump electrode 40 provided in the peripheral edge portion is larger than a width W1 of the bump electrode 40a provided in the central portion. In addition, in the column direction, a width W4 of the bump electrode 40 provided in the peripheral edge portion is larger than a width W3 of the bump electrode 40a provided in the central portion.

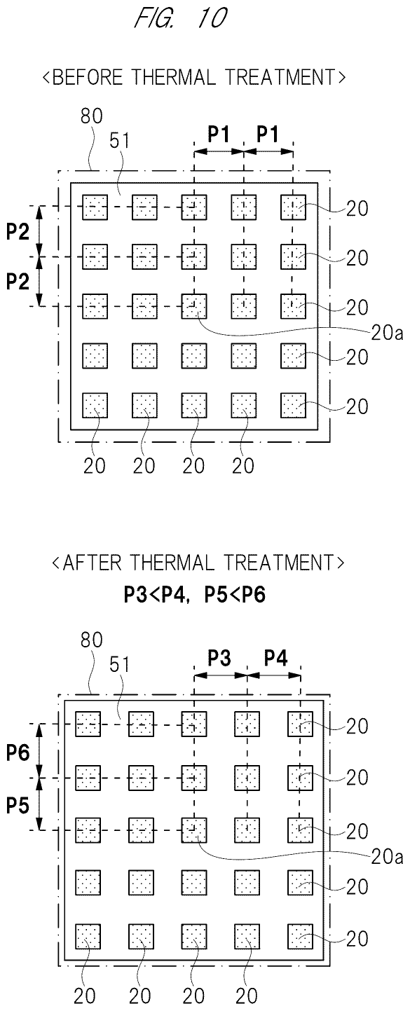

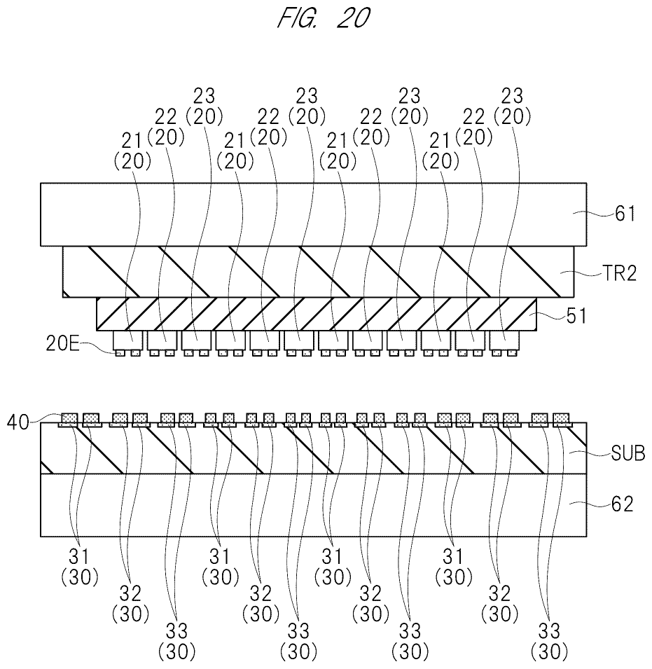

The reason why the planar areas and widths of the plurality of bump electrodes 40 are made different in this way will be described with reference to FIG. 10 to FIG. 13. Note that, in FIG. 10, the number, size, and others of the LED elements 20 are simplified as compared with the illustration in FIG. 20 and others described later in order to make the description easily understood.

When the plurality of LED elements 20 are mounted from the transfer substrate TR2 to the mounting region 80 of the array substrate SUB, the plurality of LED elements 20 are attached to the adhesive resin layer 51 of the transfer substrate TR2. As illustrated in FIG. 10, the plurality of LED elements 20 are arranged in a matrix on the adhesive resin layer 51.

When the LED elements 20 (electrodes 20E) are bonded to the bump electrodes 40, a thermal treatment is applied to the bump electrodes 40 in order to melt the bump electrodes 40. This thermal treatment causes thermal expansion in the adhesive resin layer 51, and the pitches of the plurality of LED elements 20 gradually increase as approaching the peripheral edge portion of the mounting region 80 from the central portion of the mounting region 80.

In other words, due to the thermal treatment mentioned above, the pitches of the plurality of LED elements 20 increase in the row direction as the distance in the row direction from an LED element 20a provided in the central portion increases, and increase in the column direction as the distance in the column direction from the LED element 20a increases.

Namely, before the thermal treatment, pitches P1 of the plurality of LED elements 20 in the row direction are the same as one another, and pitches P2 of the plurality of LED elements 20 in the column direction are the same as one another. However, after the thermal treatment, a pitch P4 in the row direction near the peripheral edge portion becomes larger than a pitch P3 in the row direction near the central portion, and a pitch P6 in the column direction near the peripheral edge portion becomes larger than a pitch P5 in the column direction near the central portion.

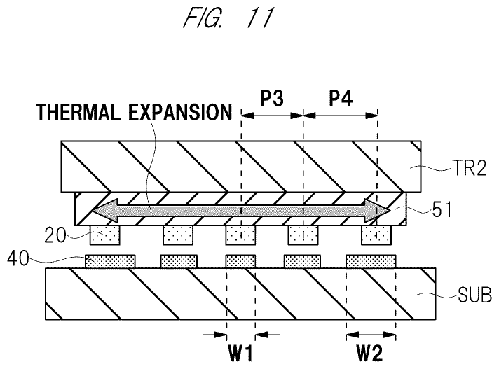

In the array substrate SUB in the first embodiment, the planar areas and widths of the plurality of bump electrodes 40 are made different in consideration of the thermal expansion caused in the adhesive resin layer 51. Therefore, as illustrated in FIG. 11, even when the pitches of the plurality of LED elements 20 change, the LED elements 20 (electrodes 20E) can be favorably bonded to the bump electrodes 40.

### <Comparison Between Studied Example and First Embodiment>>

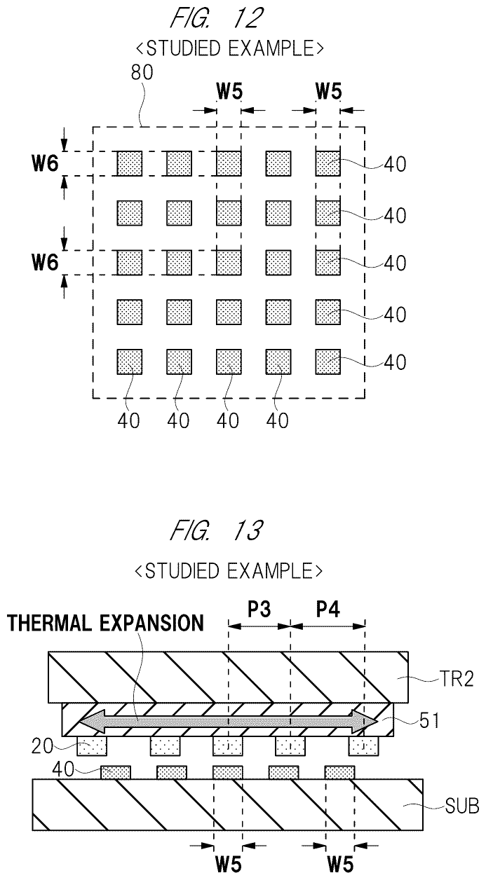

FIG. 12 and FIG. 13 illustrate a display device in a studied example, which the inventor of this application has studied.

As illustrated in FIG. 12, in the studied example, the planar areas and widths of the plurality of bump electrodes 40 are almost equal to each other unlike the first embodiment. Namely, in the plurality of bump electrodes 40 in the studied example, a width W5 of the bump electrodes 40 in the row direction and a width W6 of the bump electrodes 40 in the column direction are equal to each other.

Therefore, as illustrated in FIG. 13, when the thermal expansion occurs in the adhesive resin layer 51 and the pitches of the plurality of LED elements 20 change, the LED elements 20 (electrodes 20E) and the bump electrodes 40 are more likely to be misaligned as approaching the peripheral edge portion of the mounting region 80. As a result, the problem that the LED elements 20 are not electrically connected to the array substrate SUB may occur.

As described above, in the first embodiment, the planar areas and widths of the plurality of bump electrodes 40 are made different in consideration of the thermal expansion caused in the adhesive resin layer 51. Therefore, it is possible to solve the problem of the studied example and to improve the reliability of the display device DSP1.

### <Method of Manufacturing Display Device>

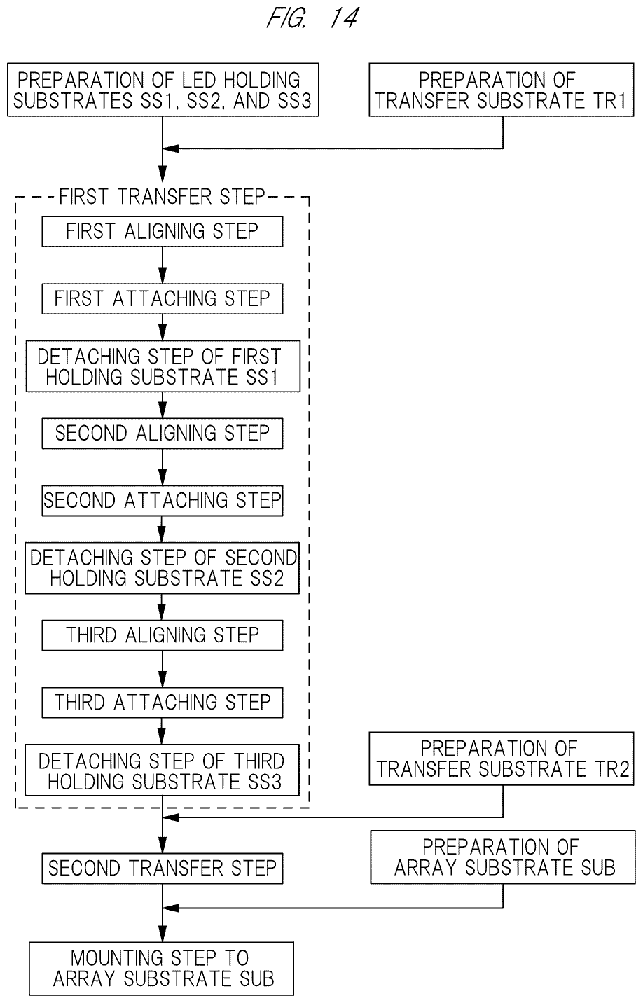

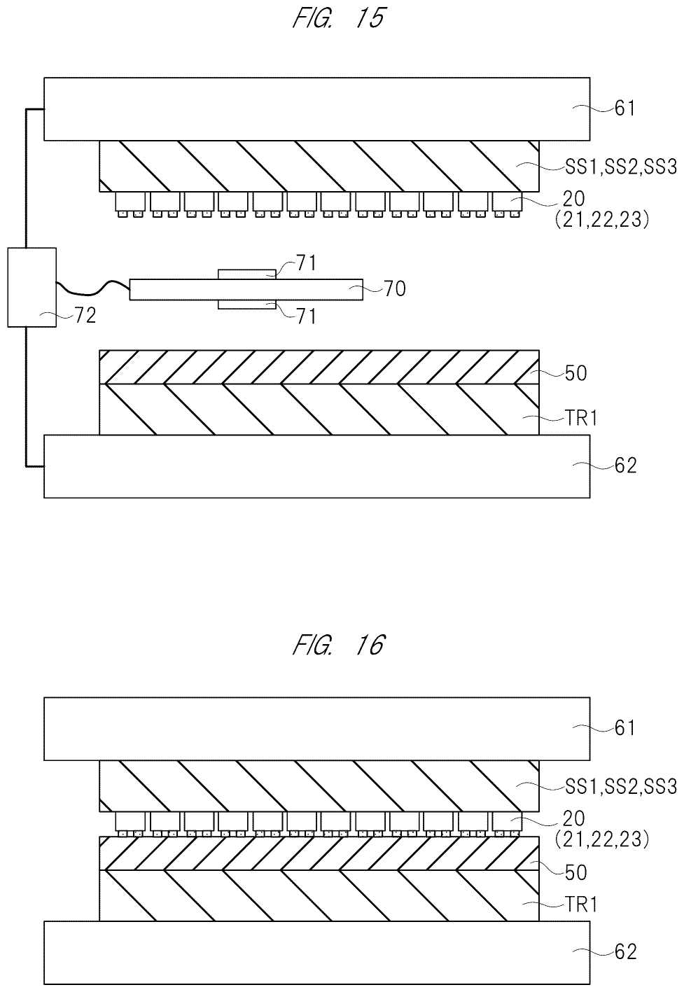

Each manufacturing step included in a method of manufacturing the display device DSP1 in the first embodiment will be described below with reference to FIG. 14 to FIG. 20. The description will be basically given along the flowchart in FIG. 14, and each cross-sectional view in FIG. 15 to FIG. 20 is used as needed.

As illustrated in FIG. 14, the plurality of LED elements 20 are transferred from the substrates SS1, SS2, and SS3 to the plurality of transfer substrates TR1 in a “first transfer step”, transferred from the plurality of transfer substrates TR1 to the transfer substrate TR2 in a “second transfer step”, and then mounted on the array substrate SUB from the transfer substrate TR2.

First, the substrates SS1, SS2, and SS3 described with reference to FIG. 5 and FIG. 6, the transfer substrate TR1 described with reference to FIG. 7, the transfer substrate TR2 described with reference to FIG. 7, and the array substrate SUB described with reference to FIG. 8 and FIG. 9 are prepared. Next, the “first transfer step” is performed using the substrates SS1, SS2, and SS3 and the transfer substrate TR1.

### <<First Aligning Step>>

As illustrated in FIG. 15, the substrate SS1 and the transfer substrate TR1 are placed such that the plurality of LED elements 20 (LED elements 21) and the adhesive resin layer 50 face each other. The substrate SS1 is placed on a stage 61 and the transfer substrate TR1 is placed on a stage 62. A camera unit 70 equipped with a camera 71 is passed between the plurality of LED elements 21 and the adhesive resin layer 50 to photograph the plurality of LED elements 21 and the adhesive resin layer 50. Based on positional information of the plurality of photographed LED elements 21 and positional information of the photographed adhesive resin layer 50, the substrate SS1 and the transfer substrate TR1 are aligned with each other.

The stage 61 can hold the substrate SS1. The stage 62 can hold the transfer substrate TR1. As a method of holding the substrate SS1 and the transfer substrate TR1, for example, a method of holding it by suction or a method of fixing a peripheral edge portion of the substrate SS1 or the transfer substrate TR1 with a fixing jig (not illustrated) may be adopted. In addition, the stage 61 and the stage 62 are electrically connected to a control device 72. The control device 72 can move the stage 61 and the stage 62 in desired directions such as the horizontal direction and the vertical direction.

The camera unit 70 is disposed between the substrate SS1 and the transfer substrate TR1, and is electrically connected to the control device 72. The camera unit 70 includes the camera 71 on each of the side closer to the stage 61 and the side closer to the stage 62. By the control of the control device 72, the camera unit 70 can move in the horizontal direction between the substrate SS1 and the transfer substrate TR1 and photographs the substrate SS1 and the transfer substrate TR1 as appropriate.

The image data obtained by the camera unit 70 is output to the control device 72. The control device 72 calculates the positional information of the LED elements 21 and the positional information of the adhesive resin layer 50 based on each image data, and moves the stage 61 and the stage 62 to proper positions. Note that the alignment marks AM1 (see FIG. 7) may be photographed to obtain the positional information of the transfer substrate TR1, and the stage 62 may be moved based on the positional information of the alignment marks AM1.

### <<First Attaching Step>>

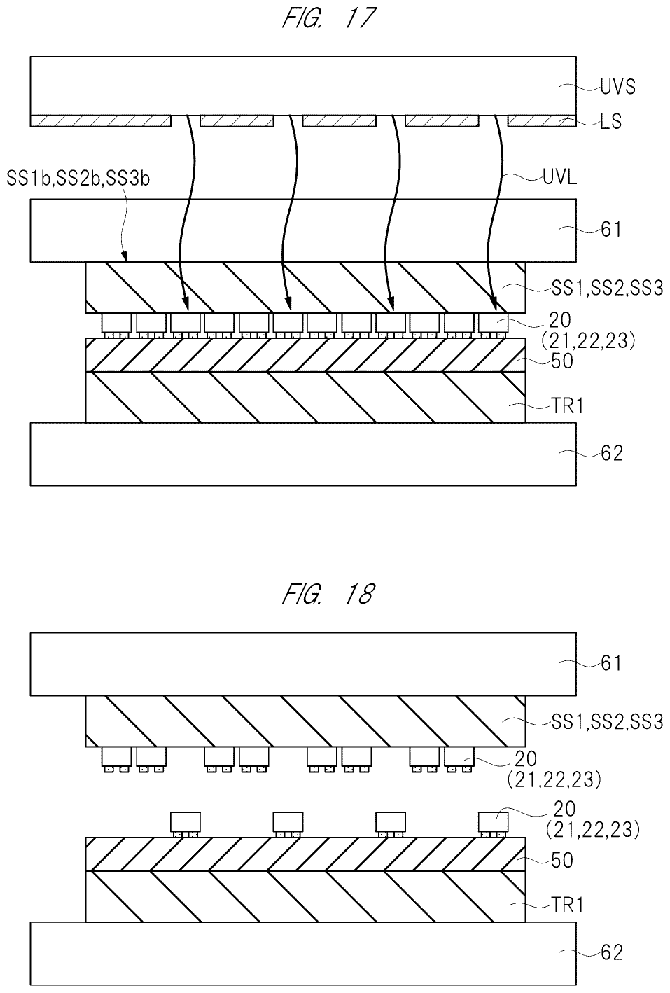

As illustrated in FIG. 16, the plurality of LED elements 21 are attached to the adhesive resin layer 50 by bringing the substrate SS1 and the transfer substrate TR1 close to each other. Specifically, the electrodes 20E in the LED elements 21 are adhered to the adhesive resin layer 50.

### <<Detaching Step of First Holding Substrate>>

In a step of detaching the plurality of LED elements 21 from the substrate SS1, for example, a technique referred to as the laser lift-off is used. As illustrated in FIG. 17, an ultraviolet irradiation device UVS is disposed on the side closer to the surface SS1b of the substrate SS1. The ultraviolet irradiation device UVS is provided with a light blocking film LS having a plurality of openings. An ultraviolet laser UVL irradiated from the ultraviolet irradiation device UVS is irradiated to the LED elements 21 through the plurality of openings and does not pass through the light blocking film LS.

Some LED elements 21 out of the plurality of LED elements 21 attached to the adhesive resin layer 50 are selectively irradiated with the ultraviolet laser UVL from the side closer to the surface SS1b of the substrate SS1. When the buffer layer 29 (see FIG. 6) is irradiated with the ultraviolet laser UVL, the surface of the buffer layer 29 is reformed, so that the LED elements 21 can be detached from the substrate SS1.

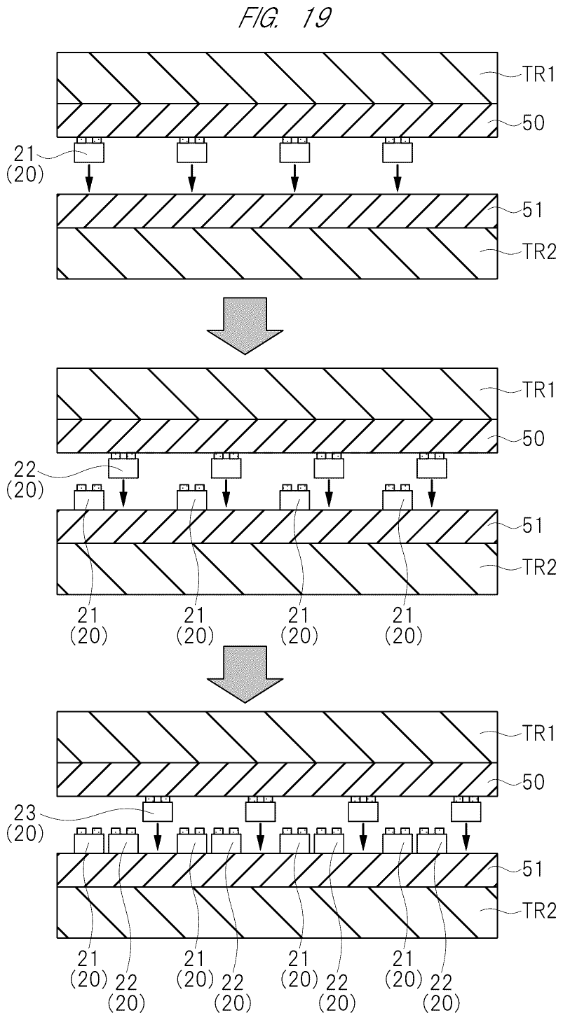

As illustrated in FIG. 18, the substrate SS1 and the transfer substrate TR1 are separated from each other. In this way, the plurality of LED elements 21 irradiated with the ultraviolet laser UVL are detached from the substrate SS1. On the other hand, the plurality of LED elements 21 not irradiated with the ultraviolet laser UVL are not detached from the substrate SS1 and are used in the transfer to another transfer substrate.

### <<Second Aligning Step, Second Attaching Step, Detaching Step of Second Holding Substrate, Third Aligning Step, Third Attaching Step, and Detaching Step of Third Holding Substrate>>

Steps similar to the “first aligning step”, the “first attaching step”, and the “detaching step of first holding substrate” described with reference to FIG. 15 to FIG. 18 are performed for the plurality of LED elements 22 of the substrate SS2 and the plurality of LED elements 23 of the substrate SS3. In this way, the plurality of LED elements 22 are transferred from the substrate SS2 to another transfer substrate TR1, and the plurality of LED elements 23 are transferred from the substrate SS3 to another transfer substrate TR1,

### <<Second Transfer Step>>

FIG. 19 illustrates a “second transfer step”. In the “second transfer step”, the plurality of LED elements 21 are transferred at once from the transfer substrate TR1 to the transfer substrate TR2, the plurality of LED elements 22 are transferred at once from another transfer substrate TR1 to the transfer substrate TR2, and the plurality of LED elements 23 are transferred at once from another transfer substrate TR1 to the transfer substrate TR2.

In the second transfer step, first, the transfer substrate TR1 and the transfer substrate TR2 are placed such that the adhesive resin layer 50 and the adhesive resin layer 51 face each other. Next, the transfer substrate TR1 and the transfer substrate TR2 are aligned with each other.

Though not illustrated, the stage 61, the stage 62, the camera unit 70, and the control device 72 are used in this alignment similarly to the alignment in FIG. 15. The camera unit 70 is passed between the plurality of LED elements 21 and the adhesive resin layer 51 to photograph the plurality of LED elements 21 and the adhesive resin layer 51. Based on positional information of the plurality of photographed LED elements 21 and positional information of the photographed adhesive resin layer 51, the transfer substrate TR1 and the transfer substrate TR2 are aligned with each other. Note that the alignment marks AM1 of the transfer substrates TR1 and TR2 (see FIG. 7) may be photographed to obtain the positional information of the transfer substrates TR1 and TR2, and the alignment may be performed based on the positional information of the alignment marks AM1.

Next, the plurality of LED elements 21 attached to the adhesive resin layer 50 are attached to the adhesive resin layer 51 of the transfer substrate TR2 by bringing the transfer substrate TR1 on which the plurality of LED elements 21 have been transferred and the transfer substrate TR2 close to each other. Then, by separating the transfer substrate TR1 and the transfer substrate TR2 from each other, the plurality of LED elements 21 are detached from the transfer substrate TR1 while the plurality of LED elements 21 are attached to the adhesive resin layer 51 because the adhesive strength of the adhesive resin layer 51 is greater than the adhesive strength of the adhesive resin layer 50.

In the same manner, the plurality of LED elements 22 attached to the adhesive resin layer 50 are attached to the adhesive resin layer 51 of the transfer substrate TR2 by bringing the transfer substrate TR1 on which the plurality of LED elements 22 have been transferred and the transfer substrate TR2 close to each other. Then, by separating the transfer substrate TR1 and the transfer substrate TR2 from each other, the plurality of LED elements 22 are detached from the transfer substrate TR1. Also, the plurality of LED elements 23 attached to the adhesive resin layer 50 are attached to the adhesive resin layer 51 of the transfer substrate TR2 by bringing the transfer substrate TR1 on which the plurality of LED elements 23 have been transferred and the transfer substrate TR2 close to each other. Then, by separating the transfer substrate TR1 and the transfer substrate TR2 from each other, the plurality of LED elements 23 are detached from the transfer substrate TR1.

In the step of transferring the plurality of LED elements 22, the LED elements 22 are arranged between the adjacent LED elements 21. Also, in the step of transferring the plurality of LED elements 23, the LED elements 23 are arranged between the LED elements 21 and the LED elements 22 adjacent to each other.

### <<Mounting Step to Array Substrate>>

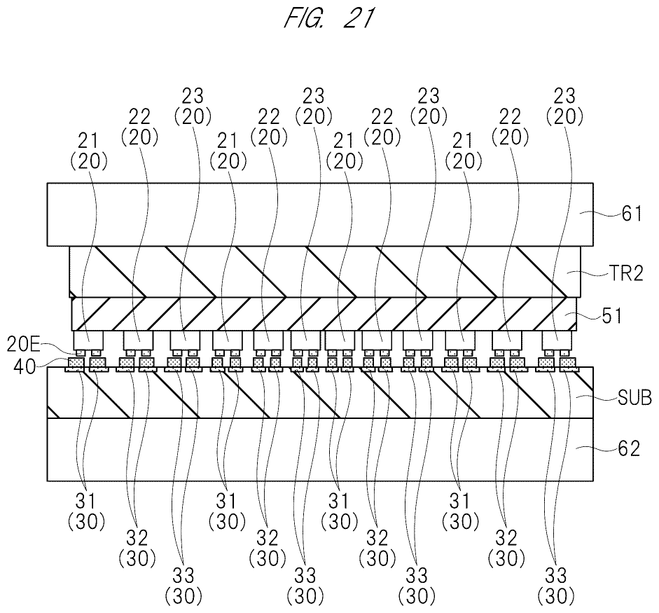

FIG. 20 and FIG. 21 illustrate a state where the plurality of LED elements 20 (21, 22, and 23) are mounted to the array substrate SUB. In this mounting step, the plurality of LED elements 21, the plurality of LED elements 22, and the plurality of LED elements 23 are mounted at once from the transfer substrate TR2 to the array substrate SUB. Note that the array substrate SUB illustrated in FIG. 20 and FIG. 21 is a part of the array substrate SUB illustrated in FIG. 9 and corresponds to one mounting region 80.

First, as illustrated in FIG. 20, the transfer substrate TR2 and the array substrate SUB are placed such that the plurality of LED elements 20 and the bump electrodes 40 face each other. Next, the transfer substrate TR2 and the array substrate SUB are aligned with each other. Though not illustrated, the camera unit 70 and the control device 72 are used in this alignment similarly to the alignment in FIG. 15.

The transfer substrate TR2 is placed on the stage 61 and the array substrate SUB is placed on the stage 62. The camera unit 70 is passed between the plurality of LED elements 20 and the plurality of bump electrodes 40 to photograph the plurality of LED elements 20 and the alignment marks AM2 (see FIG. 9). Based on positional information of the plurality of photographed LED elements 20 and positional information of the photographed alignment marks AM2, the stage 61 and the stage 62 are moved to proper positions, whereby the transfer substrate TR2 and the array substrate SUB are aligned with each other.

Next, as illustrated in FIG. 21, the transfer substrate TR2 and the array substrate SUB are brought close to each other, and thermal treatment is applied to the plurality of bump electrodes 40 in a state where the plurality of LED elements 20 are attached to the adhesive resin layer 51. As a result, the plurality of bump electrodes 40 are melted, and the electrodes 20E of the plurality of LED elements 20 are bonded to the plurality of bump electrodes 40. As a heat source for heating the bump electrodes 40, for example, a method of irradiating the bump electrodes 40 with laser light can be used.

As described above with reference to FIG. 10 and FIG. 11, the thermal expansion occurs in the adhesive resin layer 51 due to the thermal treatment, and the pitches of the plurality of LED elements 20 gradually increase as approaching the peripheral edge portion of the mounting region 80 from the central portion of the mounting region 80. However, since the planar areas of the bump electrodes 40 provided in the peripheral edge portion of the mounting region 80 are larger than the planar area of the bump electrode 40 provided in the central portion of the mounting region 80, the electrodes 20E of the plurality of LED elements 20 and the plurality of bump electrode 40 can be favorably bonded to each other without misalignment.

Next, the transfer substrate TR2 and the array substrate SUB are separated from each other. Since the bonding strength between the electrode 20E and the bump electrode 40 is greater than the bonding strength between the LED element 20 and the adhesive resin layer 51, the plurality of LED elements 20 are detached from the transfer substrate TR2. In the manner described above, the mounting of the plurality of LED elements 20 to one mounting region 80 is completed.

By repeating the “first transfer step”, the “second transfer step”, and the “mounting step to array substrate SUB” illustrated in FIG. 14, the plurality of LED elements 20 can be mounted in each of the plurality of mounting regions 80. In this manner, the display device DSP1 in the first embodiment is manufactured.

Note that FIG. 14 illustrates an example in which three types of LED elements are mounted in order, but the number of types of the LED elements to be mounted is not limited to three. For example, in the case of the method of manufacturing a display device in which two types of LED elements are mounted, the steps from the “third aligning step” to the “detaching step of third holding substrate” illustrated in FIG. 14 can be omitted. Also, in the case of the method of manufacturing a display device in which four or more types of LED elements are mounted, after the “detaching step of third holding substrate”, the “aligning step”, the “attaching step”, and the “detaching step of holding substrate” are repeatedly performed for LED elements of a different type from the LED elements of the first to third types.

Further, FIG. 9 illustrates the array substrate SUB having four mounting regions 80, but the number of mounting regions 80 is not limited to four. The number of mounting regions 80 may be less than four and five or more.

A person having ordinary skill in the art can conceive of various alterations and corrections within a range of the idea of the present invention, and it is interpreted that the alterations and corrections also belong to the scope of the present invention. For example, the embodiment obtained by performing addition or elimination of components or design change or the embodiment obtained by performing addition or reduction of process or condition change to the embodiment described above by a person having an ordinary skill in the art is also included in the scope of the present invention as long as it includes the gist of the present invention.

The present invention can be applied to display devices and electronic devices incorporating display devices.

What is claimed is:

1. A method of manufacturing a display device comprising:
(a) a step of preparing a light emitting element holding substrate on which a plurality of inorganic light emitting elements are formed, a second substrate having a second adhesive resin layer, and an array substrate having a plurality of terminals and a plurality of bump electrodes formed on the plurality of terminals;
(b) after the step (a), a step of attaching the plurality of inorganic light emitting elements on the light emitting element holding substrate to the second adhesive resin layer;
(c) after the step (b), a step of applying a thermal treatment to the plurality of bump electrodes in a state where the plurality of inorganic light emitting elements are attached to the second adhesive resin layer, whereby first electrodes of the plurality of inorganic light emitting elements are bonded to the plurality of bump electrodes; and
(d) after the step (c), detaching the plurality of inorganic light emitting elements from the second substrate,
wherein the array substrate has a mounting region to which the plurality of inorganic light emitting elements are mounted from the second substrate, and
wherein planar areas of the bump electrodes provided in a peripheral edge portion of the mounting region are larger than a planar area of the bump electrode provided in a central portion of the mounting region.

2. The method of manufacturing the display device according to claim 1,
wherein a first substrate having a first adhesive resin layer is also prepared in the step (a), and
wherein the step (b) includes:
(b1) a step of attaching the plurality of inorganic light emitting elements on the light emitting element holding substrate to the first adhesive resin layer and detaching the plurality of inorganic light emitting elements from the light emitting element holding substrate; and
(b2) a step of attaching the plurality of inorganic light emitting elements attached to the first adhesive resin layer to the second adhesive resin layer and detaching the plurality of inorganic light emitting elements from the first substrate.

3. The method of manufacturing the display device according to claim 2,
wherein the step (b1) includes:
(b11) a step of attaching the plurality of inorganic light emitting elements on the light emitting element holding substrate to the first adhesive resin layer;
(b12) a step selectively irradiating some of inorganic light emitting elements out of the plurality of inorganic light emitting elements attached to the first adhesive resin layer with ultraviolet laser; and
(b13) a step of detaching the plurality of inorganic light emitting elements irradiated with the ultraviolet laser from the light emitting element holding substrate.

4. The method of manufacturing the display device according to claim 1,
wherein planar areas of the plurality of bump electrodes gradually increase as approaching the peripheral edge portion from the central portion.

5. The method of manufacturing the display device according to claim 4,
wherein, due to the thermal treatment in the step (c), pitches of the plurality of inorganic light emitting elements gradually increase as approaching the peripheral edge portion from the central portion.

6. The method of manufacturing the display device according to claim 1,
wherein the plurality of bump electrodes are arranged in a matrix, and
wherein widths of the plurality of bump electrodes gradually increase in a first row direction as a distance in the first row direction from the bump electrode provided in the central portion increases, and gradually increase in a first column direction as a distance in the first column direction from the bump electrode provided in the central portion increases.

7. The method of manufacturing the display device according to claim 6,
wherein, after the step (b), the plurality of inorganic light emitting elements are arranged in a matrix on the second adhesive resin layer, and
wherein, due to the thermal treatment in the step (c), pitches of the plurality of inorganic light emitting elements gradually increase in a second row direction as a distance in the second row direction from the inorganic light emitting element provided in the central portion increases, and gradually increase in a second column direction as a distance in the second column direction from the inorganic light emitting element provided in the central portion increases.

8. The method of manufacturing the display device according to claim 1,
wherein the array substrate has a plurality of the mounting regions, and
wherein the plurality of inorganic light emitting elements are mounted in each of the plurality of mounting regions by repeating the step (b), the step (c), and the step (d).

9. A display device comprising:
a plurality of inorganic light emitting elements each having a first electrode; and
an array substrate having a plurality of terminals and a plurality of bump electrodes formed on the plurality of terminals,
wherein the first electrodes of the plurality of inorganic light emitting elements are bonded to the plurality of bump electrodes,
wherein the array substrate has a mounting region to which the plurality of inorganic light emitting elements are mounted from one transfer substrate, and
wherein planar areas of the bump electrodes provided in a peripheral edge portion of the mounting region are larger than a planar area of the bump electrode provided in a central portion of the mounting region.

10. The display device according to claim 9,
wherein planar areas of the plurality of bump electrodes gradually increase as approaching the peripheral edge portion from the central portion.

11. The display device according to claim 10,
wherein pitches of the plurality of inorganic light emitting elements gradually increase as approaching the peripheral edge portion from the central portion.

12. The display device according to claim 9,
wherein the plurality of bump electrodes are arranged in a matrix, and
wherein widths of the plurality of bump electrodes gradually increase in a first row direction as a distance in the first row direction from the bump electrode provided in the central portion increases, and gradually increase in a first column direction as a distance in the first column direction from the bump electrode provided in the central portion increases.

13. The display device according to claim 12,
wherein the plurality of inorganic light emitting elements are arranged in a matrix, and
wherein pitches of the plurality of inorganic light emitting elements gradually increase in a second row direction as a distance in the second row direction from the inorganic light emitting element provided in the central portion increases, and gradually increase in a second column direction as a distance in the second column direction from the inorganic light emitting element provided in the central portion increases.

14. The display device according to claim 9,
wherein the array substrate has a plurality of the mounting regions.
